(19) United States
(12) Patent Application Publication
(10) Pub. No.: US 2025/0286341 A1
(43) Pub. Date: Sep. 11, 2025

(54) METHOD FOR PREPARING OPTOELECTRONIC INTEGRATED SEMICONDUCTOR PACKAGING STRUCTURE

(71) Applicant: SJ Semiconductor(Jiangyin) Corporation, Jiangyin City (CN)

(72) Inventors: Yenheng CHEN, Jiangyin City (CN); Chengchung LIN, Jiangyin City (CN)

(73) Assignee: SJ Semiconductor(Jiangyin) Corporation, Jiangyin City, JS (CN)

(21) Appl. No.: 18/842,788

(22) PCT Filed: Jun. 9, 2023
(86) PCT No.: PCT/CN2023/099290

§ 371 Date: Aug. 29, 2024

(30) Foreign Application Priority Data
Nov. 28, 2022 (CN) 202211503702.2

(51) Int. Cl. H01S 5/02212; H01S 5/0234; H01S 5/0237; H01S 5/024; H01S 5/183

(52) U.S. Cl. CPC H01S 5/02212; H01S 5/0234; H01S 5/0237; H01S 5/02469; H01S 5/183

(57) ABSTRACT

A method for preparing an optoelectronic integrated semiconductor packaging structure that employs 2.5D integrated packaging. Both photonic and electronic integrated chips at different sizes are flip-chip mounted within the same packaging structure. This approach allows for the co-packaging of photonic and electronic integrated chips, effectively reducing the line width and spacing of the packaging structure. It enables high-density integration and packaging of chips from different size with varying process nodes through back-end processes.

### FIELD OF TECHNOLOGY

The present disclosure relates to the field of semiconductor packaging, and in particular relates to a method for preparing an optoelectronic integrated semiconductor packaging structure.

### BACKGROUND

The pursuit of integrated circuit packaging is to achieve circuits that are not only lower in cost and more reliable, but also faster and denser. The integration density of various electronic components will be enhanced by continually minimizing the feature size in future.

By 2022, global internet traffic is expected to reach nearly 400 exabytes (EB) per month, and the demand for data center interconnect bandwidth will continue to grow at an exponential rate. It is predicted that by 2030, with the continued growth in data center energy consumption, the global electricity usage of data centers will exceed 3 petawatt-hours (PWh) and could even reach up to 8 PWh. To meet the demands of internet traffic, data center node bandwidth needs to reach 10 terabits per second (Tb/s). To mitigate the trend of increasing data center energy consumption, it is essential to find ways to reduce the power consumption of systems and components.

Photonic technologies offer advantages such as low signal attenuation, low energy consumption, high bandwidth, and CMOS compatibility, all of which directly impact I/O bandwidth and energy consumption. Therefore, incorporating silicon photonics technology is essential to enhance I/O bandwidth and minimize energy consumption. In this context, the integration of photonics and electronics is crucial. Finding an effective way to combine and package photonic integrated circuits (PICs) and electronic integrated circuits (EICs) remains a pressing challenge.

Currently, fabricating most of the existing three-dimensional stacked optoelectronic packaging structures directly apply bonding the photonic integrated chip and electronic integrated chip on the same substrate, and electrically connecting them to the substrate through wire-bonds or Flip-Chip techniques. However, the silicon photonics process dimensions are relatively larger compared to electronic chip processes. For instance, the most advanced silicon photonics process doesn't require beyond 45 nm and 32 nm, which are significantly larger than the sub-10 nm process nodes used in electronic chips. As a result, the performance of existing optoelectronic integrated packaging structures often falls short of meeting the high-density integration requirements.

In the existing technology, there is also the use of system-on-chip (SOC) packaging to change the chip design in order to improve the density of package integration, but this approach needs to be improved in the front-channel process on the optical chip, however to match the optical chip and the electrical chip at the process node of 10 nm or less, will undoubtedly increases the packaging process cost.

### SUMMARY

As the minimum feature size in the IC core decreases (e.g., Complementary Metal-Oxide-Semiconductor (CMOS) node <7 nm), the electrical input/output (I/O) in-circuit connection is reduced. Internal wiring (e.g., copper wiring) will be the bottleneck of data transfer rate. In order to improve the performance of the package structure (e.g., data transfer rate, I/O bandwidth, data transfer length, etc.), 2.5D integrated packaging technology and optical I/O internal wiring can be implemented. In addition, by implementing the 2.5D technology and the optical I/O internal connection, the size of the packaging structure can be miniaturized and the transmission cost can be reduced.

The present disclosure provides a method for preparing an optoelectronic integrated semiconductor packaging structure by integrating a photonic chip with an electronic chip in a high-density integrated package. The method comprises the following steps:
providing a silicon substrate, wherein the silicon substrate comprises a first surface and an opposing second surface;
forming a first redistribution layer on the first surface of the silicon substrate, wherein the first redistribution layer comprises a silicon-based dielectric layer and a first metal wiring layer;
forming metal pillars on the first redistribution layer, wherein the metal pillars comprise first ends and opposing second ends, and the first ends of the metal pillars are electrically connected to the first metal wiring layer;
bonding photonic integrated chips and electronic integrated chips to the first redistribution layer, wherein both the photonic integrated chips and the electronic integrated chips are electrically connected to the first metal wiring layer, and the first redistribution layer beneath the photosensitive areas of the photonic integrated chips comprise the silicon-based dielectric layer;
forming an encapsulation layer that covers the photonic integrated chips and the electronic integrated chips, thinning the top surface of the encapsulation layer to expose the second ends of the metal pillars;
forming a second redistribution layer on the encapsulation layer, wherein the second redistribution layer comprises a second dielectric layer and a second metal wiring layer, and the second metal wiring layer is electrically connected to the metal pillars;
patterning the silicon substrate and the first redistribution layer from the second surface of the substrate to form through-holes that extend inward to penetrate through the silicon substrate and the first redistribution layer, wherein the through-holes are optically connected to the photosensitive areas of the photonic integrated chips;
bonding a lens onto the second surface of the silicon substrate, forming a sealed cavity between the lens and the photonic integrated chips; and
providing a board, bonding the board to the second redistribution layer, wherein the board is electrically connected to the second metal wiring layer.

Optionally, the method for forming the first redistribution layer comprises the Damascene process.

Optionally, the resulting optoelectronic integrated semiconductor packaging structure has a minimum line width in a range of 0.4 to 0.8 μm and a minimum line spacing in a range of of 0.4 to 15 μm.

Optionally, the material of the silicon-based dielectric layer includes at least one of silicon dioxide, silicon nitride, silicon carbide, or silicon oxynitride.

Optionally, the photonic integrated chips comprise VCSEL (vertical cavity surface emitting laser) chips, and the electronic integrated chips comprise BiCMOS (bipolar CMOS) chips.

Optionally, the photosensitive areas of the photonic integrated chips are physically separated from the encapsulation layer.

Optionally, a protective layer is formed around the photosensitive areas of the photonic integrated chips, spaces are left between the photosensitive areas and the first redistribution layer, and the spaces are in communication with the through-holes.

Optionally, the protective layer is formed around the photosensitive areas of the photonic integrated chips by applying a dispensing method after bonding the photonic integrated chips onto the first redistribution layer.

Optionally, a transparent material is adhered to the surfaces of the photosensitive areas of the photonic integrated chips using a transparent adhesive material.

Optionally, a thermally removable material is attached to the photosensitive areas of the photonic integrated chips.

Optionally, the method further comprises, after the board is bonded to the second redistribution layer, providing a heat dissipation cover plate and bonding the heat dissipation cover plate to the second surface of the board and the remaining silicon substrate, and leaving the lens over the photosensitive areas exposed.

As described above, the optoelectronic integrated semiconductor packaging structure and preparation method of the present invention use 2.5D integration packaging, wherein optical integrated chips and electrical integrated chips at different sizes are both flip-chipped mounted onto the packaging layer. This enables the co-packaging of optical and electronic integrated chips, which effectively reduces the line width and pitch of the packaging structure, and achieves high-density integration and packaging of chips with different sizes.

### BRIEF DESCRIPTION OF THE DRAWINGS

FIG. 1 shows a flowchart of a method for preparing an optoelectronic integrated semiconductor packaging structure according to one embodiment of the present disclosure.

FIG. 2 shows a schematic diagram of an intermediate structure obtained after forming a first redistribution layer on a silicon substrate.

FIG. 3 shows a schematic diagram of an intermediate structure obtained after forming metal pillars.

FIG. 4 shows a schematic diagram of an intermediate structure obtained after bonding photonic integrated chips and electronic integrated chips.

FIG. 5 shows a schematic diagram of an intermediate structure obtained after forming an encapsulation layer.

FIG. 6 shows a schematic diagram of an intermediate structure obtained after thinning the encapsulation layer to expose the second ends of the metal pillars.

FIG. 7 shows a schematic diagram of an intermediate structure obtained after forming a second redistribution layer over the chips.

FIG. 8 shows a schematic diagram of an intermediate structure obtained after forming through-holes into the substrate.

FIG. 9 shows a schematic diagram of an intermediate structure obtained after bonding a lens on the substrate.

FIG. 10 shows a schematic diagram of an intermediate structure obtained after bonding a second redistribution layer and a board on the opposing side of the substrate.

FIG. 11 shows a schematic diagram of an intermediate structure obtained after bonding a heat dissipation cover plate over the package.

### Reference Numerals

100 Silicon substrate
210 First redistribution layer
211 First metal wiring layer
212 Silicon-based dielectric layer
220 Second redistribution layer
221 Second metal wiring Layer
222 Dielectric layer
300 Metal pillars
410 Electronic integrated chips
420 Photonic integrated chips
500 Encapsulation layer
610 Optical path
620 Through-holes
630 Cavity
700 Inert metal layer
800 Lens
900 Board
110 Bottom filling layer
120 Heat dissipation cover plate
130 Metal bumps

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers. Wherein, when an element is “fixed onto” or “disposed on” another element, it may be directly or indirectly on the other element. When an element is “attached to” or “connected to” another element, it may be directly or indirectly attached/connected to the other element.

Expressions such as “between . . . ” may be used herein to indicate that two endpoints of the range are included, and expressions such as “several” may be used to indicate two or more, unless explicitly and specifically qualified otherwise. In addition, the terms like “first” and “second” are used for descriptive purpose only, and are not to be construed as indicating or implying relative importance or implicitly specifying numbers of technical features indicated. Thus, features qualified with terms like “first” and “second” may explicitly or implicitly comprise one or more such features.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

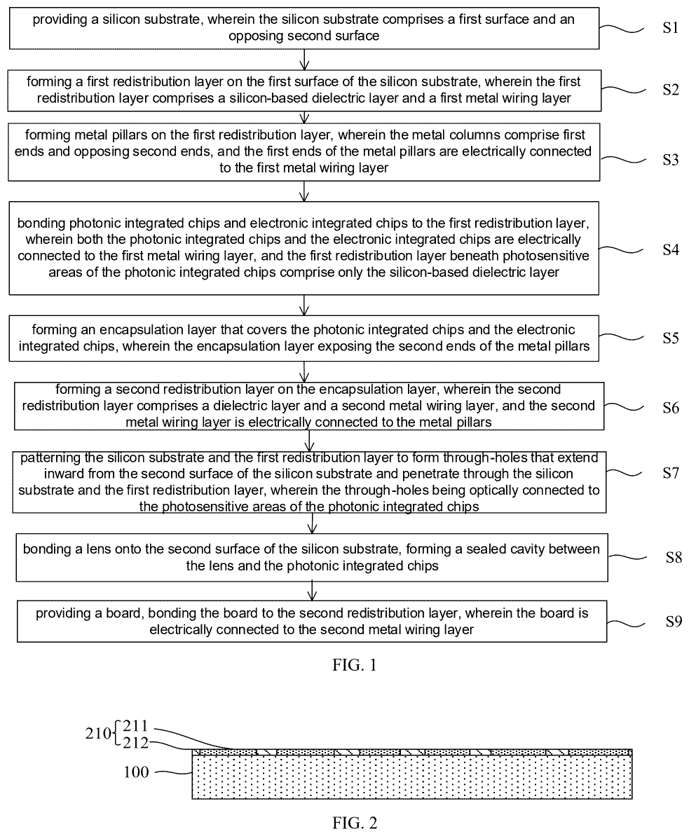

As shown in FIG. 1, the present disclosure provides a method for preparing an optoelectronic integrated semiconductor packaging structure. By using 2.5D integration packaging, photonic integrated chips and electronic integrated chips with different node sizes can both be Flip-Chipped into the encapsulation layer. This allows for the co-packaging of photonic integrated chips and electronic integrated chips, effectively reducing the line width and pitch of the packaging structure. Consequently, high-density integration and packaging of chips with different process nodes from different eras can be achieved through subsequent processes.

The following provides a detailed introduction to the preparation of the optoelectronic integrated semiconductor packaging structure with reference to FIG. 2-FIG. 11.

First, referring to FIG. 2, execute step S1 to provide a silicon substrate 100, the silicon substrate 100 comprises a first surface and an opposing second surface.

Specifically, the silicon substrate 100 may be a wafer-level silicon substrate with diameter of 8 inches or 12 inches to further enhance process efficiency; however, the size of the silicon substrate 100 is not limited to these dimensions.

Further, execute Step S2, where a first redistribution layer 210 is formed on the first surface of the silicon substrate. The first redistribution layer 210 comprises a first metal wiring layer 211 and a silicon-based dielectric layer 212.

The material of the silicon-based dielectric layer 212 is at least one of silicon dioxide, silicon nitride, silicon carbide, or silicon oxynitride. As an example, the method for forming the first redistribution layer 210 comprises the Damascene process: the silicon-based dielectric layer 212 is formed through chemical vapor deposition first, and is patterned into through-holes and groves after, and metal is deposited into the via holes and groves, followed by planarization to form the first metal wiring layer 211. To facilitate the formation of the first metal wiring layer 211, seed layers (not shown in figures) can be deposited or electroplated on the silicon-based dielectric layer 212 and inside the grooves and through-holes openings patterned in the silicon-based dielectric layer 212.

In some embodiments, the seed layer (not shown in figures) is a metal layer, which can be a single layer or a composite layer comprising multiple sub-layers made of different materials. In some embodiments, the seed layer comprises a titanium layer and a copper layer positioned over top of the titanium layer. The seed layer can be formed using methods such as physical vapor deposition. Then, a conductive material is formed on the seed layer, and this conductive material fills the grooves and through-holes in the dielectric layer to form the conductive lines and via holes. In some embodiments, the conductive material can be formed by plating. The conductive material may comprise metals such as copper, titanium, tungsten, or aluminum.

Then, a planarization process is performed to remove excess portions of the seed layer and the conductive material that are deposited on the dielectric layer outside the grooves and through-holes openings to obtain the clean first metal wiring 211. In some embodiments, the planarization process may include chemical mechanical polishing (CMP), mechanical grinding, or other suitable processes.

Specifically, the number of layers of the first redistribution layer 210 can be selected as needed. The first redistribution layer 210 can achieve smaller line widths and line spacings to meet the requirements for high-density connections in subsequent stages. The material of the first metal wiring layer 211 can be copper. gold, aluminum, or other materials may also be used as needed.

To facilitate the subsequent etching to form through-holes 620 into the substrate (as shown in FIG. 8), in one embodiment, the dielectric layer in the first redistribution layer 210 is preferably made of silicon dioxide, and the substrate is preferably made of silicon. This allows for the simultaneous etching of both the silicon substrate 100 and the first redistribution layer 210 in the same etching step, thereby conveniently forming the through-holes 620.

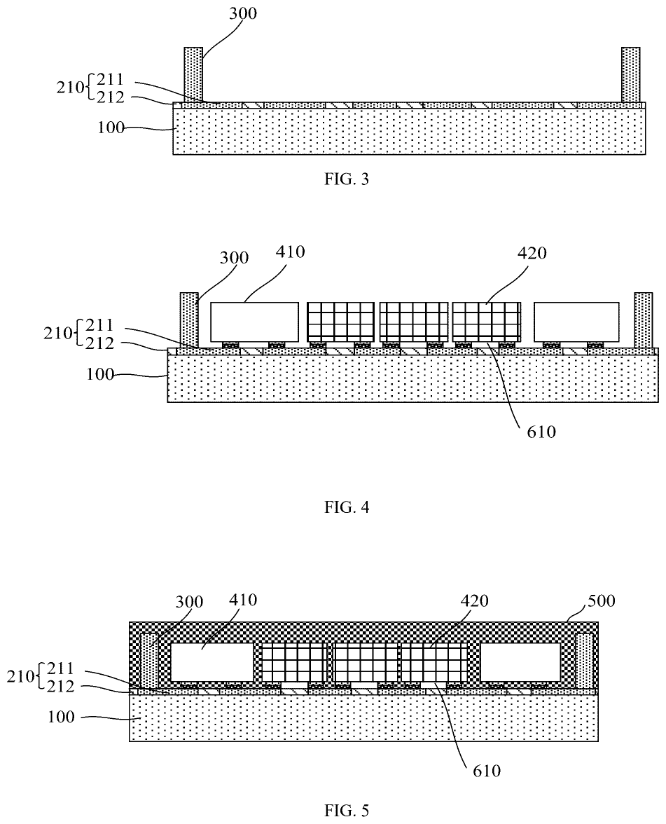

Next, referring to FIG. 3 and FIG. 4, first execute step S3, where metal pillars 300 are formed on the first redistribution layer 210. The metal pillars 300 comprise first ends and opposing second ends, with the first ends of the metal pillars 300 electrically connected to the first metal wiring layer 210. The material of the metal pillars 300 can be copper. The metal pillars 300 can be arranged based on the locations of the first metal wiring layer 211 and the subsequent placement of electronic integrated chips 410 and photonic integrated chips 420. Preferably, the metal pillars 300 are positioned at the edges of the first redistribution layer 210. In other words, the metal pillars 300 are located in the periphery of the electronic integrated chips 410 and the photonic integrated chips 420.

Optionally, the metal pillars 300 can be positioned between the electronic integrated chips 410 and the photonic integrated chips 420, further shortening the transmission path between the electronic integrated chips 410 and the photonic integrated chips 420.

Next, further referring to FIG. 4, execute step S4 by bonding the photonic integrated chips 420 and the electronic integrated chips 410 to the first redistribution layer 210. Both the photonic integrated chips 420 and the electronic integrated chips 410 are electrically connected to the first metal wiring layer 211 and are positioned such that the first redistribution layer 210 beneath the photosensitive area (not shown in figures) of the photonic integrated chips 420 contain only the silicon-based dielectric layer 212. The photosensitive areas (not shown in figures) of the photonic integrated chips 420 is located in the middle of the active surface of the photonic integrated chips 420, and is situated between the photonic integrated chips 420 and the electrical connection to the first metal wiring layer 211.

Specifically, the electronic integrated chips 410 and the photonic integrated chips 420 are electrically connected to the first metal wiring layer 211 in the first redistribution layer 210 using a Flip-Chip bonding method. The electronic integrated chips 410 can be on a process node of 10 nm or less, while the photonic integrated chips 420 can be at a larger process dimension, such as 45 nm or 32 nm.

In one embodiment, the photonic integrated chips 420 are preferably VCSEL chips, and the electronic integrated chips 410 are preferably BiCMOS chips. However, the types of the electronic integrated chips 410 and the photonic integrated chips 420 are not limited to these.

Specifically, the photosensitive areas of the photonic integrated chips 420 are isolated from an encapsulation layer 500 formed in subsequent steps. As an example, after the photosensitive areas of the photonic integrated chips 420 are electrically connected to the first metal wiring layer 211, a protective layer (not shown in figures) is formed around the periphery of the photonic integrated chips 420 on the first redistribution layer 210. This forms an optical path610 between the photosensitive areas and the first redistribution layer 210. The protective layer is a sealing adhesive, which can be applied at the edge of the photonic integrated chips 420 by dispensing or brushing techniques. As an example, the photosensitive areas of the photonic integrated chips 420 can also be protected by attaching a transparent material with a transparent adhesive to isolate the photosensitive area from the encapsulation layer 500 formed in subsequent steps. As an example, the photosensitive areas of the photonic integrated chips 420 can also be covered with a thermally removable material. After the formation of the encapsulation layer 500 in subsequent steps, the thermally removable material is used to create the optical path 610 between the photosensitive areas and the first redistribution layer 210 through the principle of thermal removal. The thermally removable material may be paraffin, polystyrene, or other materials that can be heated to disappear. Preferably, the heat removable material is optically transparent.

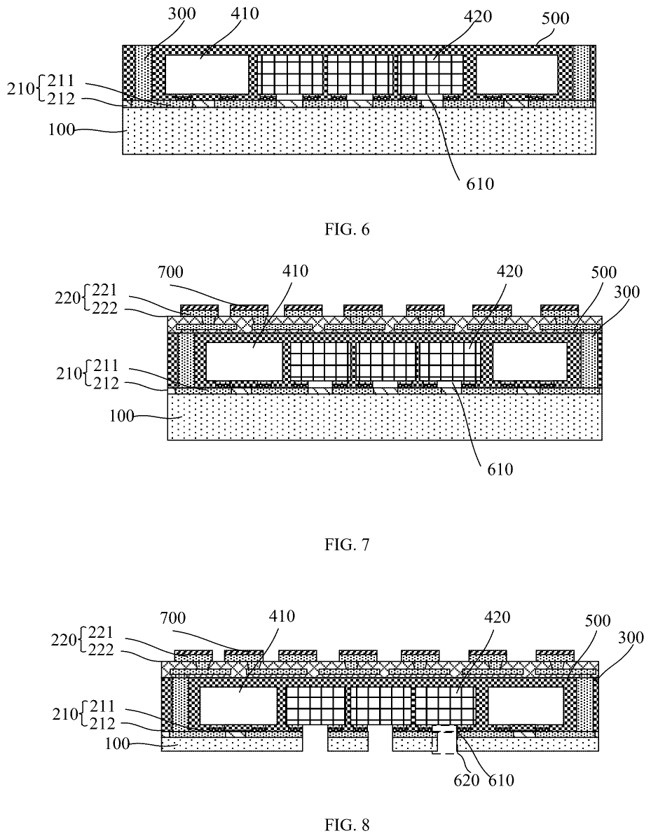

Next, referring to FIG. 5 and FIG. 6, execute step S5, wherein the encapsulation layer 500 is formed on the side of the first redistribution layer 210 away from the silicon substrate 100. The encapsulation layer 500 encapsulates the photonic integrated chips 420, the electronic integrated chips 410, and the metal pillars 300, while exposing the second ends of the metal pillars 30.

Specifically, referring to FIG. 5, the upper surface of the initially formed encapsulation layer 500 may be higher than the second ends of the metal pillars 300. After forming the encapsulation layer 500, a thinning process is performed to expose the second ends of the metal pillars 300. This thinning process may include, but is not limited to, a chemical-mechanical planarization (CMP) process to reduce the thickness of the encapsulation layer 500 and reveal the second end of the metal pillars 300, thereby reducing the packaging size, as shown in FIG. 6. The material of the encapsulation layer 500 may be polymers, polyimides, silicones, epoxy resins, etc. The method for forming the encapsulation layer 500 is preferably a molding method that allows for precise dimensioning. However, the material and method for preparing the encapsulation layer 500 are not limited to these options.

Next, referring to FIG. 7, execute step S6, wherein a second redistribution layer 220 is formed on the encapsulation layer 500. The second redistribution layer 220 comprises a dielectric layer 222 and a second metal wiring layer 221. The second metal wiring layer 221 is electrically connected to the metal pillars 300. The second redistribution layer 220 can be formed using methods such as the damascene process. The structure, material, and preparation method of the second redistribution layer 220 are not overly restricted here.

Further, an inert metal layer 700 can be formed over the exposed surface of the second metal wiring layer 221 in the second redistribution layer 220. The inert metal layer 700 serves to protect the second metal wiring layer 221, such as to prevent oxidation of a copper metal wiring layer 221 and to enhance the stability of the device. Preferably, the inert metal layer 700 is an Au metal layer.

Next, referring to FIG. 8, execute step S7, wherein the silicon substrate 100 and the first redistribution layer 210 are patterned to form through-holes 620 that extends inward from the second surface of the silicon substrate 100 and penetrates through both the silicon substrate 100 and the first redistribution layer 210. The through-holes 620 are in communication with the optical path 610.

Specifically, in one embodiment, since the first redistribution layer 210 below the photosensitive areas only comprise the silicon-based dielectric layer 212 and does not have the first metal wiring layer 211, and because the dielectric layer in the first redistribution layer 210 is the silicon-based dielectric layer 212 with the substrate preferably being the silicon substrate 100, the through-holes 620 can be formed by etching both the silicon substrate 100 and the silicon-based dielectric layer 212 in the same etching step, thus reducing process complexity.

Further, as needed during the formation of the through-holes 620, the silicon substrate 100 may be thinned first before proceeding with the etching process. Additionally, during the thinning process, a temporary bonding substrate (not shown in figures) may be provided to bond with the second redistribution layer 220 and offer support. The specific choice of whether to use a temporary bonding substrate can be made based on requirements.

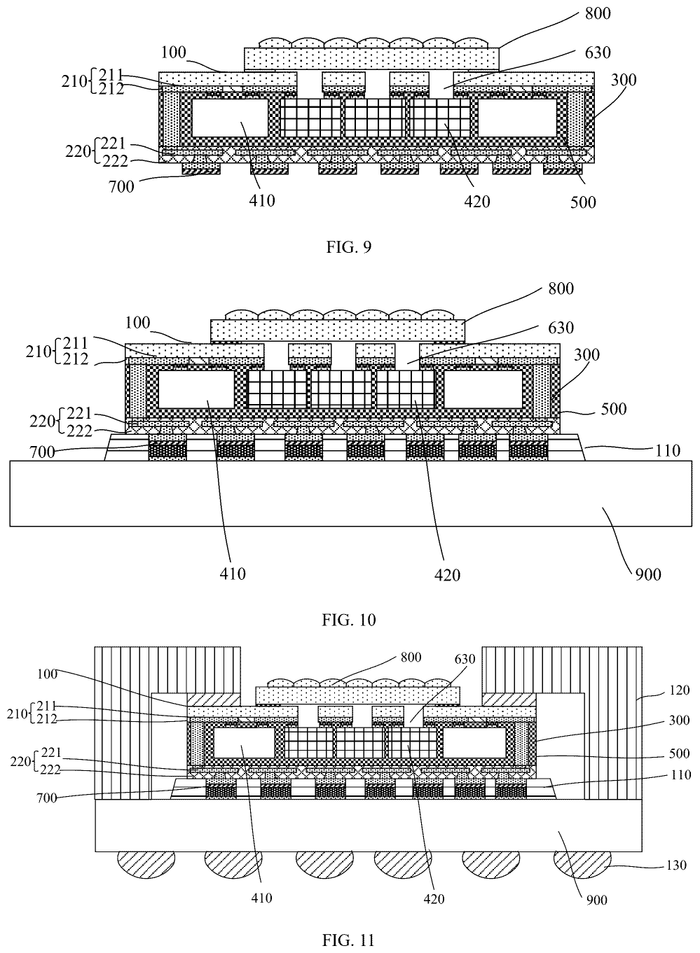

Next, referring to FIG. 9, execute step S8, wherein a lens 800 is bonded to the central area on the second surface of the silicon substrate 100, forming a sealed cavity 630 between the lens 800 and the photonic integrated chips 420.

Specifically, after bonding the lens 800, a sealing layer can be formed around the lens 800 using methods such as dispensing adhesive. This creates the sealed cavity 630, thereby providing protection for the photonic integrated chips 420. The edge of the lens 800 is spaced from the edge of the second surface of the silicon substrate 100.

Next, referring to FIG. 10, execute step S9, wherein a board 900 is provided. The second redistribution layer 220 is bonded to the board 900 through the inert metal layer 700 and other supportive conductive layers attached with adhesives between the inert metal layer 700 and the board 900. The board 900 is electrically connected to the second metal wiring layer 221. The board 900 may comprise a PCB substrate.

As an example, a bottom filling layer 110 may be formed between the second redistribution layer 220 and the board 900. This bottom filling layer 110 serves to protect the second redistribution layer 220 and the board 900. The material of the bottom filling layer 110 may be selected based on requirements, as long as it is an insulating material.

Next, referring to FIG. 11, execute step S10, wherein a heat dissipation cover plate 120 is provided. The heat dissipation cover plate 120 is bonded to the second surface of the board 900 and the silicon substrate 100, exposing the lens 800.

Specifically, the heat dissipation cover plate 120 may be made of aluminum or other materials such as iron, copper, etc. Furthermore, the bonding of the heat dissipation cover plate 120 to the board 900 and the silicon substrate 100 should use materials with matching thermal expansion coefficients to ensure good bonding and prevent deformation due to heat. To facilitate subsequent electrical connections, the surface of the board 900 may also be formed with metal bumps 130, such as solder balls made using a reflow soldering process.

In one embodiment, the heat dissipation cover 120 is located at the periphery of the lens 800.

As an example, the resulting optoelectronic integrated semiconductor packaging structure has a minimum line width in a range of 0.4 to 0.8 μm and a minimum line spacing in a range of 0.4 to 15 μm.

Specifically, based on the first redistribution layer 210, the second redistribution layer 220, and the metal pillars 300, the minimum line width in the optoelectronic integrated semiconductor packaging structure can reach from 0.4 to 0.8 μm, such as 0.4 μm, 0.5 μm, 0.6 μm, 0.8 μm, etc. Similarly, the minimum line spacing in the optoelectronic integrated semiconductor packaging structure can also reach from 0.4 to 0.8 μm, such as 0.4 μm, 0.5 μm, 0.6 μm, 0.8 μm, etc. This allows for the co-packaging of the photonic integrated chips 420 and the electronic integrated chips 410, and effectively reduces the line width and spacing of the packaging structure. As a result, high-density integration packaging of chips from different eras with different process nodes can be achieved solely through the back-end packaging process.

Referring to FIG. 2-FIG. 11, the present disclosure also provides an optoelectronic integrated semiconductor packaging structure. The optoelectronic integrated semiconductor packaging structure comprises the silicon substrate 100, the first redistribution layer 210, the metal pillars 300, the photonic integrated chips 420, the electronic integrated chips 410, the encapsulation layer 500, the second redistribution layer 220, the through-holes 620, the lens 800, the board 900, and the heat dissipation cover plate 120.

The silicon substrate 100 comprises a first surface and an opposing second surface; the first redistribution layer 210 is located on the first surface of the silicon substrate 100 and comprises the silicon-based dielectric layer 212 and the first metal wiring layer 211; the metal pillars 300 are positioned on the first redistribution layer 210 and away from the silicon substrate 100. They comprise a first end and an opposing second end, with the first ends of the metal pillars 300 electrically connected to the first metal wiring layer 211; the photonic integrated chips 420 and the electronic integrated chips 410 are bonded to the first redistribution layer 211 and are electrically connected to the first metal wiring layer 211. Additionally, only the silicon-based dielectric layer 212 is located in the first redistribution layer 210 below the photosensitive areas (not shown); the encapsulation layer 500 covers the photonic integrated chips 420 and the electronic integrated chips 410, and the encapsulation layer 500 exposes the second ends of the metal pillars 300; the second redistribution layer 220 is located over top of the encapsulation layer 500 and comprises the dielectric layer 222 and the second metal wiring layer 221. The second metal wiring layer 221 is electrically connected to the metal pillars 300; The through-holes 620 extend inward from the second surface of the silicon substrate 100, penetrating through the silicon substrate 100 and the first redistribution layer 210. The through-holes 620 provide optical communication with the photosensitive areas of the photonic integrated chips 420; the lens 800 is bonded to the second surface of the silicon substrate 100, and the sealed cavity 630 is located between the lens 800 and the optical integrated chip 420 to prevent contamination of the photosensitive areas of the photonic integrated chips 420 and thereby maintain its performance; the board 900 is bonded to the second redistribution layer 220, and the board 900 is electrically connected to the second metal wiring layer 221; the heat dissipation cover plate 120 is bonded to the second surface of both the board 900 and the silicon substrate 100, and exposes the lens 800 so that light can pass through the lens 800 and the through-holes 620 to reach the photosensitive areas of the photonic integrated chips 420.

In one embodiment, the photosensitive areas of the photonic integrated chips 420 are separated from the encapsulation layer 500. A protective layer is arranged around the periphery of the photonic integrated chips 420 to form optical path 610 between the photosensitive areas and the first redistribution layer 210, and the optical path 610 are in communication with the through-holes 620.

In other embodiments, a transparent material is adhered to the surface of the photosensitive areas of the photonic integrated chips 420 using a transparent adhesive material to protect the photosensitive areas and isolate it from the encapsulation layer 500.

In other embodiments, a thermally removable material is attached to the surface of the photosensitive areas of the photonic integrated chip 420 to protect the photosensitive areas and isolate it from the encapsulation layer 500. Preferably, the thermally removable material is transparent. The thermally removable material disappears through heat after the formation of the packaging layer 500.

An inert metal layer 700 is also formed above said second metal wiring layer 221 on the surface of said second rewiring layer 220. Preferably, the inert metal layer 700 is an Au metal layer.

Specifically, the optoelectronic integrated semiconductor packaging structure can be prepared using the above method, but is not limited to this. In one embodiment, the optical integrated semiconductor packaging structure is prepared using the above-mentioned method, so details regarding the preparation and structure of the optical integrated semiconductor packaging structure are not elaborated here.

As an example, in the optoelectronic integrated semiconductor packaging structure, the minimum line width can be in a range 0.4-0.8 μm, and the minimum line spacing can be in a range 0.4-0.8 μm.

Specifically, based on the first redistribution layer 210, the second redistribution layer 220, and the metal pillars 300, the minimum line width in the optoelectronic integrated semiconductor packaging structure can reach from 0.4-0.8 μm, such as 0.4 μm, 0.5 μm, 0.6 μm, 0.8 μm, etc. The minimum line spacing in the optical integrated semiconductor packaging structure can reach from 0.4-15 μm, such as 0.4 μm, 0.5 μm, 0.6 μm, 0.8 μm, 2 μm, 5 μm, 10 μm, 15 μm, etc. This enables the co-packaging of the photonic integrated chips 420 and the electronic integrated chips 410, and effectively reduces the line width and spacing of the packaging structure, thus allowing high-density integration and packaging of chips with different process nodes from different eras through the post-packaging process.

As an example, the photonic integrated chips 420 may comprise VCSEL chips, while the electronic integrated chips 410 may comprise BiCMOS chips. However, the types of the photonic integrated chips 420 and the electronic integrated chips 410 are not limited to these examples.

In summary, the present disclosure provides a method for preparing an optoelectronic integrated semiconductor packaging structure that employs 2.5D integrated packaging. By Flip-Chip mounting photonic integrated chips and electronic integrated chips with different node sizes in the encapsulation layer, it enables the co-packaging of these chips. This approach effectively reduces the line width and spacing of the packaging structure, allowing high-density integration and packaging of chips from different eras with varying process nodes through subsequent processing steps.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for preparing an optoelectronic integrated semiconductor packaging structure, comprising:
providing a silicon substrate, wherein the silicon substrate comprises a first surface and an opposing second surface;
forming a first redistribution layer on the first surface of the silicon substrate, wherein the first redistribution layer comprises a first dielectric layer and a first metal wiring layer, wherein the first dielectric layer is silicon-based;
forming metal pillars on the first redistribution layer, wherein the metal pillars comprise first ends and opposing second ends, wherein the first ends of the metal pillars are electrically connected to the first metal wiring layer;
bonding photonic integrated chips and electronic integrated chips to the first redistribution layer, wherein each of the photonic integrated chips comprises a photosensitive area, wherein both the photonic integrated chips and the electronic integrated chips are electrically connected to the first metal wiring layer, and wherein the first redistribution layer beneath the photosensitive areas of the photonic integrated chips comprises only the first silicon-based dielectric layer;
forming an encapsulation layer that covers the photonic integrated chips and the electronic integrated chips, thinning the encapsulation layer to expose the second ends of the metal pillars;
forming a second redistribution layer on the encapsulation layer, wherein the second redistribution layer comprises a second dielectric layer and a second metal wiring layer, and the second metal wiring layer is electrically connected to the metal pillars;
patterning the silicon substrate and the first redistribution layer to form through-holes that extend inward from the second surface of the silicon substrate and penetrate through the silicon substrate and the first redistribution layer, wherein the through-holes are optically connected to the photosensitive areas of the photonic integrated chips;
bonding a lens onto the second surface of the silicon substrate, forming a sealed cavity between the lens and the photonic integrated chips; and
providing a board, bonding the board to the second redistribution layer, wherein the board is electrically connected to the second metal wiring layer;

2. The method for preparing the optoelectronic integrated semiconductor packaging structure according to claim 1, wherein the method for forming the first redistribution layer comprises a Damascene process.

3. The method for preparing the optoelectronic integrated semiconductor packaging structure according to claim 1, wherein a resulting optoelectronic integrated semiconductor packaging structure has a minimum line width in a range of 0.4 to 0.8 μm and a minimum line spacing in a range of 0.4 to 15 μm.

4. The method for preparing the optoelectronic integrated semiconductor packaging structure according to claim 1, wherein a material of the first dielectric layer is at least one of silicon dioxide, silicon nitride, silicon carbide, and silicon oxynitride.

5. The method for preparing the optoelectronic integrated semiconductor packaging structure according to claim 1, wherein the photonic integrated chips comprise VCSEL chips and the electronic integrated chips comprise BiCMOS chips.

6. The method for preparing the optoelectronic integrated semiconductor packaging structure according to claim 1, wherein the photosensitive areas of the photonic integrated chips are spaced apart from the encapsulation layer.

7. The method for preparing the optoelectronic integrated semiconductor packaging structure according to claim 6, further comprising forming a protective layer around the photosensitive areas of the photonic integrated chips, and forming optical paths between the photosensitive areas and the first redistribution layer, wherein the optical paths are in communication with the through-holes.

8. The method for preparing the optoelectronic integrated semiconductor packaging structure according to claim 7, wherein the forming of the protective layer is by applying a dispensing method after bonding the photonic integrated chips onto the first redistribution layer.

9. The method for preparing the optoelectronic integrated semiconductor packaging structure according to claim 6, wherein a transparent material is adhered to surfaces of the photosensitive areas of the photonic integrated chips using a transparent adhesive material.

10. The method for preparing the optoelectronic integrated semiconductor packaging structure according to claim 6, wherein a thermally removable material is attached to the photosensitive areas of the photonic integrated chips.

11. The method for preparing the optoelectronic integrated semiconductor packaging structure according to claim 1, wherein an inert metal layer is formed above the second metal wiring layer which is exposed from the surface of the second redistribution layer; a bottom filling layer is formed between the second redistribution layer and the board.

12. The method for preparing the optoelectronic integrated semiconductor packaging structure according to claim 1, wherein the method further comprises providing a heat dissipation cover plate and bonding the heat dissipation cover plate to the second surface of the board and the silicon substrate, leaving the lens exposed, after the board is bonded to the second redistribution layer.

13. An optoelectronic integrated semiconductor packaging structure, comprising:
a silicon substrate, wherein the silicon substrate comprises a first surface and an opposing second surface;
a first redistribution layer located over the first surface of the silicon substrate, wherein the first redistribution layer comprises a first dielectric layer and a first metal wiring layer, wherein the first dielectric layer is silicon-based;
metal pillars, wherein the metal pillars are located over the first redistribution layer, wherein the metal pillars comprise first ends and opposing second ends, wherein the first ends of the metal pillars are electrically connected to the first metal wiring layer;
photonic integrated chips and electronic integrated chips, wherein the photonic integrated chips and the electronic integrated chips are bonded to the first rewiring layer and are each electrically connected to the first metal wiring layer, and wherein only the first dielectric layer is present in the first redistribution layer beneath the photosensitive areas of the photonic integrated chips;
an encapsulation layer, wherein the encapsulation layer covers the photonic integrated chips and the electronic integrated chips, and wherein second ends of the metal pillars expose from the encapsulation layer;
a second redistribution layer, located over the encapsulation layer, wherein the second redistribution layer comprises a second dielectric layer and a second metal wiring layer, wherein the second metal wiring layer is electrically connected to the metal pillars;
through-holes, wherein the through-holes extend inward from the second surface of the silicon substrate and penetrating through the silicon substrate and the first redistribution layer, wherein the through-holes provide optical communication with the photosensitive areas of the photonic integrated chips;
a lens, wherein the lens is bonded to the second surface of the silicon substrate, with a sealed cavity formed between the lens and the photonic integrated chip; and
a board, wherein the board is bonded to the second redistribution layer and the board is electrically connected to the second metal wiring layer.

14. The optoelectronic integrated semiconductor packaging structure according to claim 13, wherein the three-dimensional stacked optoelectronic packaging structure has a minimum line width in a range of 0.4 to 2 μm and a minimum line spacing in a range of 0.4 to 2 μm.

15. The optoelectronic integrated semiconductor packaging structure according to claim 13, wherein the photonic integrated chips comprise VCSEL chips, and the electronic integrated chips comprise BiCMOS chips.

16. The optoelectronic integrated semiconductor packaging structure according to claim 13, wherein the photosensitive areas of the photonic integrated chips are spaced apart from the packaging layer.

17. The optoelectronic integrated semiconductor packaging structure according to claim 16, wherein a protective layer is provided at a periphery of the photosensitive areas of the photonic integrated chips.

18. The optoelectronic integrated semiconductor packaging structure according to claim 16, wherein a transparent material is adhered to a surface of the photosensitive areas of the photonic integrated chips.

19. The optoelectronic integrated semiconductor packaging structure according to claim 16, wherein a thermally removable material is attached to the photosensitive areas of the photonic integrated chips.

20. The optoelectronic integrated semiconductor packaging structure according to claim 13, further comprising a heat dissipation cover plate, wherein the heat dissipation cover plate is bonded to the second surface of the board and the silicon substrate, leaving the lens exposed.
